(19) United States
(12) Patent Application Publication
(10) Pub. No.: US 2010/0307799 A1
(43) Pub. Date: Dec. 9, 2010

(54) Carrier Structure for Electronic Components and Fabrication Method of the same

(76) Inventor: Cheng-Feng CHIANG, Gueishan Township (TW)

Correspondence Address: HDLS IPR Services, PO Box 220746, Chantilly, VA, 20153, US

(21) Appl. No.: 12/479,791

(22) Filed: Jun. 6, 2009

(51) Int. Cl. H05K 1/03; H05K 3/10; H01K 3/22

(52) U.S. Cl. 174/255; 29/848

(57) ABSTRACT

A carrier structure for electronic components includes a carrier, an interface layer, insulation paths and a metal layer. The carrier is made of a molded plastic. A reflection cup is formed on the carrier. The carrier is etched, catalyzed and activated, then deposited Ni or Cu by chemical deposition to form an interface layer on it. Afterwards insulation paths are formed on the interface layer by ablating part of the insulation layer employing laser beam radiation, in the followed step, electroplating process is carried out using Cu, Ni, Ag or Au to form a metal layer on the interface layer thereby completing the carrier structure for electronic components.

### BACKGROUND OF THE INVENTION

1. Field of the Invention

The present invention relates to a carrier structure for electronic components, in particular, to a carrier structure for electronic components made of a highly light reflective and electrically conductive metal.

2. Description of the Prior Art

At present, the conductor lead frame for LEDS is generally formed of a conductive metallic material selected one from Cu, Al and Cu alloys by the punching process to be made into a fundamental material, after that the surface thereof is electroplated a layer of highly electrically conductive material selected one from Sb, Ag and Au, finally a cup shaped LED conductor lead frame is made up by insert molding. It is regretful that the cup shaped LED conductor lead frame is unable to serve a good light reflection effect with its reflection area.

Alternatively, the Laser Direct Structuring (LDS) process may be employed to fabricate the LED conductor lead frame. However, it is disadvantageous that a special material is needed to perform the LDS process; the electrodes and the reflection area are activated by the laser beam radiation after the material is molded. The laser radiation causes a textured reflection surface and a too large reflection area. The angle of reflection, the time limit of fabrication and the degree of texturization of the reflection surface inevitably deviate from the originally assumed values that result in affecting light reflection and the luminance of the product. Besides, the three dimensional laser radiation equipment is expensive and the time needed for fabrication is long, all these factors are added to cause a high production cost.

Incidentally, the Low Temperature Co-fired Ceramics (LTCC) can be used to form the aforesaid conductor lead frame. As the LTCC resembles the silicon material in its property, both can be bonded with lighting chips and serve excellent heat conductivity and refractory. But the product fabricated using LTCCS has the demerits that the LTCC has to be formed under the burning temperature of about 900° C., non-uniform shrinkage arises in different part, variation of electrical property and fabrication cost that result in increased production cost.

The related technique published in Taiwan Pat. No. M285037 with the title “Structure of LED Package” in which a metal layer is formed on a molded base by vacuum deposition, after that an insulation path is formed by laser beam radiation. The fabrication process requires a vacuum equipment to perform the work. The production cost is high compared with poor metal utilization efficiency. The thin metal film formed by vacuum depositing contributes to the product only low light reflection efficiency and electric conductivity.

Aiming at the above-depicted defects, the present invention is to propose a newly developed construction and fabrication method for a carrier of electronic components based on many years of experience gained through professional engagement of the inventor in the manufacturing of the related products, with continuous experimentation and improvement culminating in the development of the present invention.

### SUMMARY OF THE INVENTION

It is an object of the present invention to provide a carrier structure for electronic components having a high light reflectivity and good heat conductivity, and allowing to form electrical wiring and an insulation path on it.

It is another object of the present invention to provide a fabrication method of the aforesaid product with a simple process suitable for mass production in low cost.

To achieve the above objects, the carrier structure for electronic components according to the present invention comprises a supporting body having a carrier; an interface layer formed on the surface thereof by electroless plating; an insulation path respectively formed on the upper, lower and side surfaces of the carrier by ablating part of the surface thereof employing laser beam radiation so as to form required electric circuit and insulation paths; and a metal layer formed on the interface layer by electroplating or chemical deposition.

In another embodiment, the carrier structure of the present invention comprises a carrier with a carrier member on its surface, and at least a side arm is extended out of at least one side; and interface layer formed on the surface thereof by electroless plating; an insulation path respectively formed on the upper and lower ablated interface surface by laser radiation to form required electric circuit and insulation paths; and a metal layer formed on the interface layer be electroplating or chemical deposition.

### BRIEF DESCRIPTION OF THE DRAWINGS

The drawings disclose illustrative embodiments of the present invention, which serve to exemplify the various advantages and objects hereof, and are as follows:

FIG. 1 is a prospective view of the carrier structure in a first embodiment of the present invention.

FIG. 2 is a schematic view in a first embodiment where an interface layer is formed on the carrier.

FIG. 3 is a schematic view in a first embodiment where an insulation path is respectively formed on the interface layer on the upper and side surfaces of the carrier.

FIG. 4 is a schematic view in a first embodiment where an insulation path is respectively formed on the interface layer on the lower and side surfaces of the carrier.

FIG. 5 is a schematic view in a first embodiment where a metal layer is formed on the interface layer, and also showing the completed carrier structure for the electronic components.

FIG. 6 is a prospective view of the carrier structure in a second embodiment of the present invention.

FIG. 7 is a schematic view in a second embodiment where an interface layer is formed on the carrier.

FIG. 8 is a schematic view in a second embodiment where a front surface insulation path is formed on the interface layer on the upper surface of the carrier and its two side arms.

FIG. 9 is a schematic view in a second embodiment where a rear surface insulation path is formed on the interface layer on the lower surface of the carrier and its side arm.

FIG. 10 is a schematic view where a metal layer is formed on the interface layer.

FIG. 11 is a schematic view in a second embodiment showing a completed carrier structure.

FIG. 12 is a schematic view where a front surface insulation path is formed on the carrier and its single side arm.

FIG. 13 is a schematic view where a front surface insulation path is formed on the carrier and its plural side arms.

FIG. 14 is a schematic view where a back surface insulation path is formed on the carrier and its plural arms.

FIG. 15 is a flow chart illustrating the fabrication process according to a first embodiment of the present invention.

FIG. 16 is a flow chart illustrating the fabrication process according to a second embodiment of the present invention.

### DETAILED DESCRIPTION OF THE PREFERRED EMBODIMENT

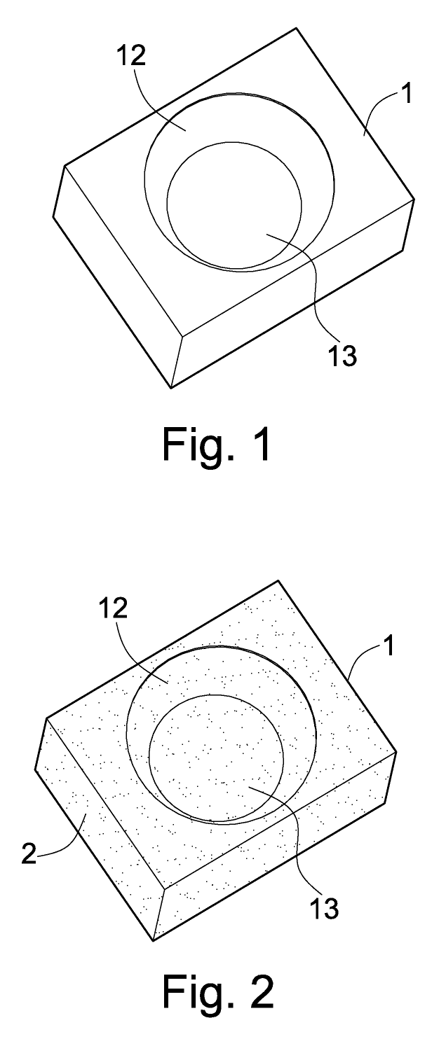

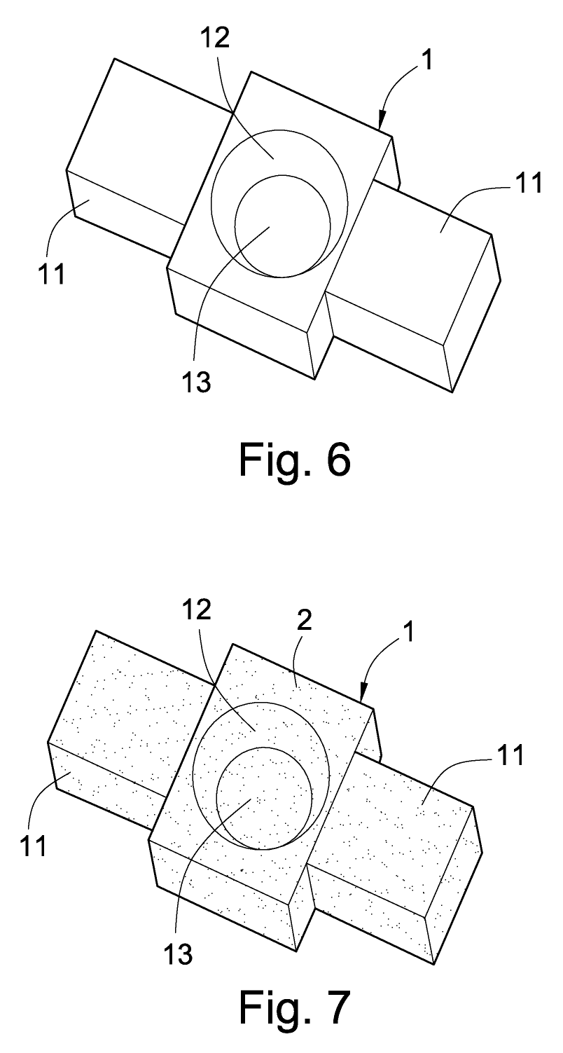

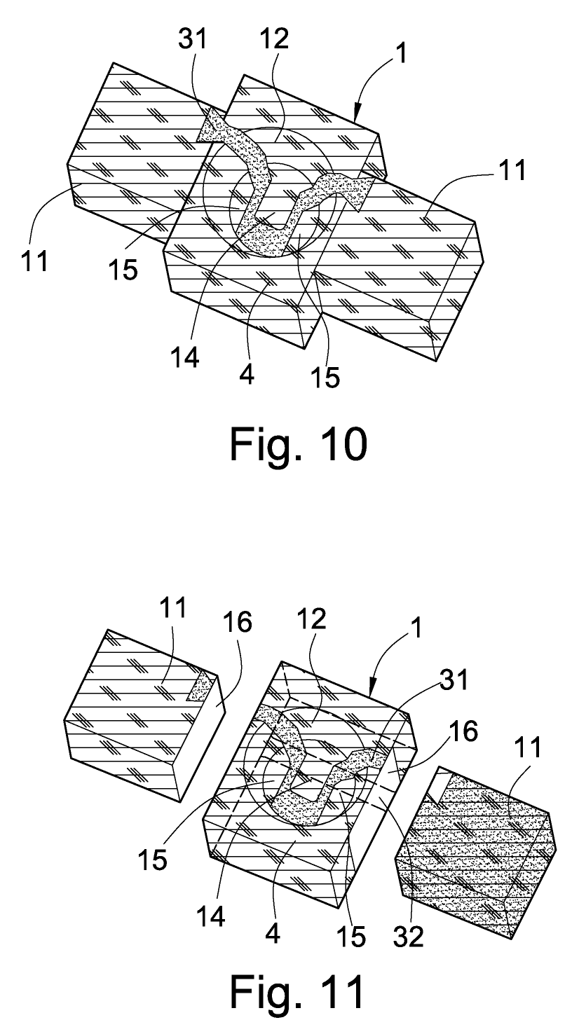

Referring to FIG. 1 through FIG. 5 (first embodiment), and FIG. 6 through FIG. 11 (second embodiment), the carrier structure for electronic components of the present invention comprises a carrier 1, an interface layer 2, a group of insulation paths 3 and a metal layer 4.

The carrier 1, which is molded of a single plastic material, has no side arm extended from the carrier 1 (see FIG. 1) but has at least a side arm 11 extended at least one side of the carrier 1 (see FIG. 6). The carrier 1 has a slanted reflection surface 12 formed downwardly on top of the carrier 1 with an inclined angle between 15°˜85°. The carrier 1 is molded of a plastic material doped with a metal catalyst, or a plastic material doped with an organic substance. Afterwards the surface of the carrier 1 is treated by etching or sand blasting as electroless pretreatment. Or the carrier 1 is molded of a plastic material without doping metal catalyst, or a plastic material without doping organic substance. Afterwards the surface thereof is textured by pre-dipping, chemical etching or sands blasting, then catalyzed and enters the chemical deposition process.

The interface layer 2 is formed by chemically depositing Ni or Cu on the surface of the metal catalyst activated carrier 1 after transformed to electroless plating process as shown in FIG. 2 or FIG. 7.

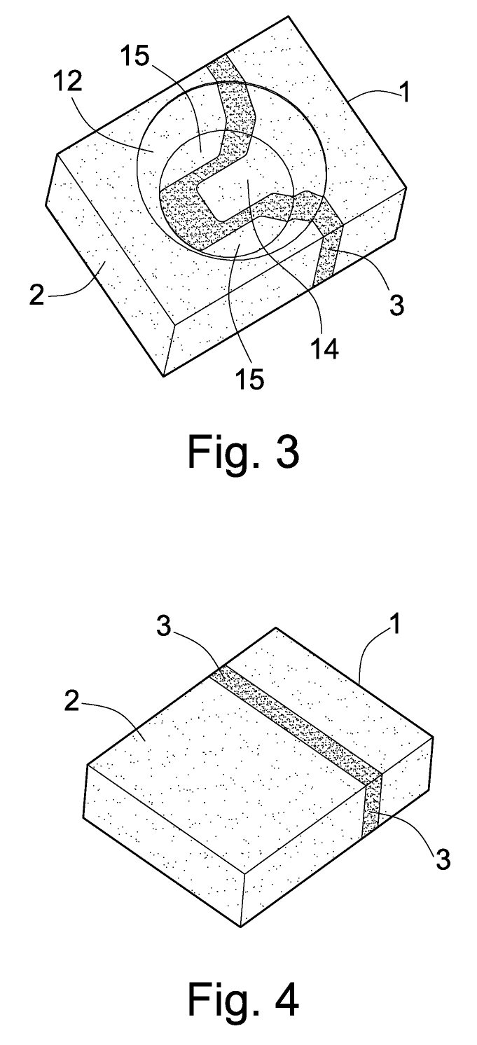

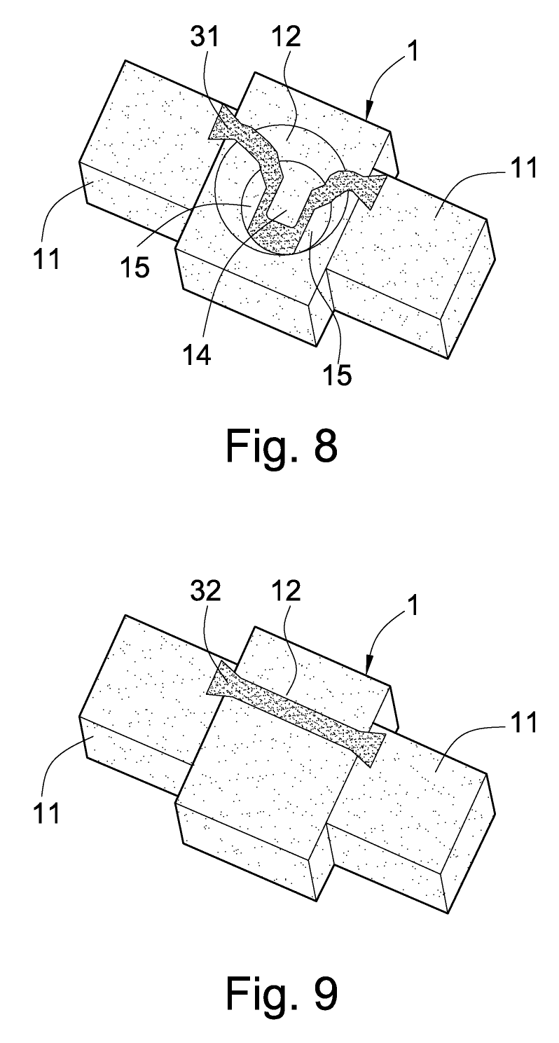

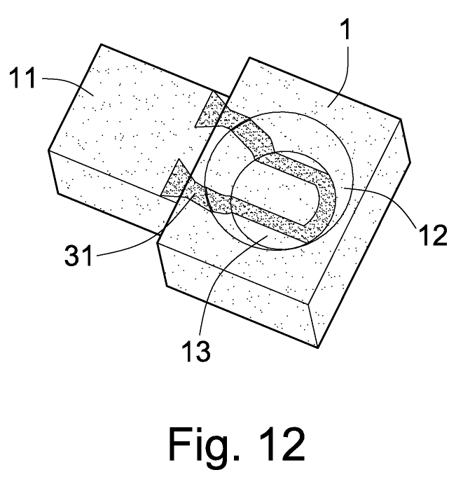

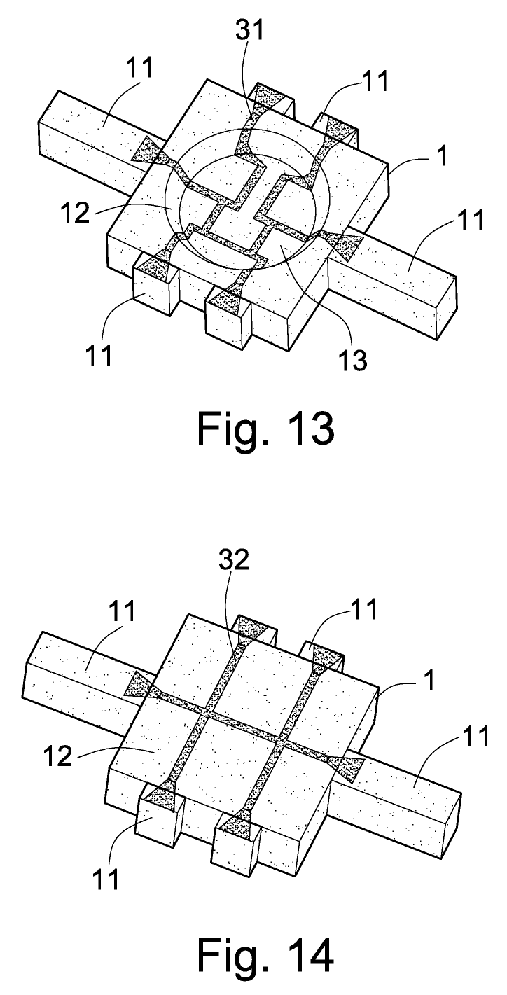

Ablating part of the interface layer 2 with laser beam radiation forms the insulation path 3. In the first embodiment, part of the interface layer 2 on the upper, side and lower surfaces on the carrier 1 is ablated such that the insulation path 3 encircling the carrier 1 is formed (see FIG. 3 and FIG. 4). In the second embodiment, a front and back surface insulation paths 31, 32 are formed by ablating part of the interface layer 2 using laser beam radiation (see FIG. 8 and FIG. 9). The front and back surface insulation paths 31, 32 formed on the interface surface are extended out of the fringe of the carrier 1 to the surface area of the side arm 11. FIG. 8 is a schematic view where a front surface insulation path 31 is formed on the upper surface of the carrier 1. FIG. 12 shows a front surface insulation path 31 is formed on the carrier 1 and its single side arm 11, and FIGS. 13 and 14 show respectively a front surface and a back surface insulation paths are formed on the carrier and its plural arms 11. The source of the laser beam is selected one from CO² laser, Nd: YAG laser, Nd:YVO4 laser and the excimer laser with the wavelength selected one from 248 nm, 308 nm, 355 nm, 532 nm, 1064 nm and 10600 nm.

The metal layer 4 is formed on the interface layer 2 by electroplating process; the metal is selected one from Cu, Ni, Ag, Au, Cr, and chemical replacement Au. The metal layer 4 is not only able to improve reflectivity of the reflection cup 13, but also contributes to free formation of wiring on the carrier 1. The light conductor lead frame made as such allows freely determining the shape of the reflection surface so as to accommodate desired number of light elements to be disposed in any figure. In the present invention, highly effective chemical deposition process and electroplating process are employed respectively to form the interface layer 2 and the metal layer 4 so as to make up a carrier structure of excellent optical reflectivity, electrical and heat conductivity with low production cost.

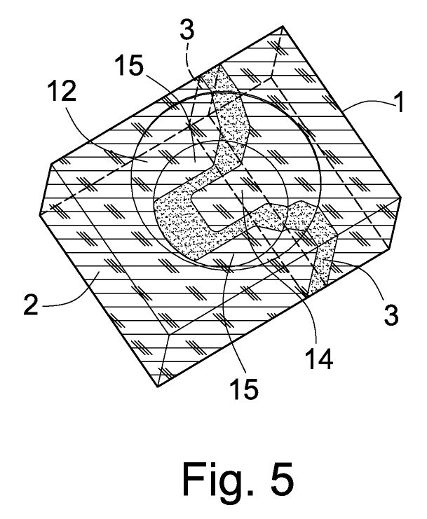

The carrier 1 is molded with a single plastic material by electroless plating to form an interface layer 2 with Ni or Cu and then an insulation path 3 in the reflection cup 13 by laser radiation to ablate part of the insulation path 3 encircling the carrier 1 of the carrier structure shown in FIG. 5. In the final stage, the side arm or arms 11 if any, is separated from the carrier 1 by cutting or punching and shearing such that a bonding face 16 between the carrier 1 and its side arm or arms 11, the front and the rear insulation paths 31, 32 split the carrier 1 into a positive pole 14 and a negative pole 15, also the reflection cup 13 is parted into a positive pole 14 and a negative pole 15 thereby completing fabrication of the carrier structure (see FIG. 11).

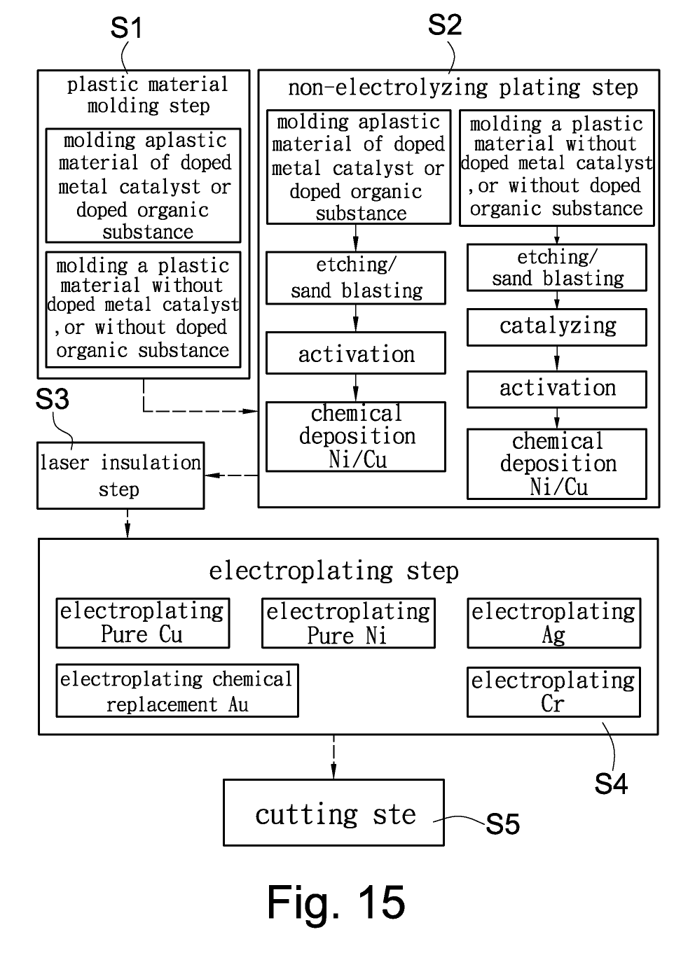

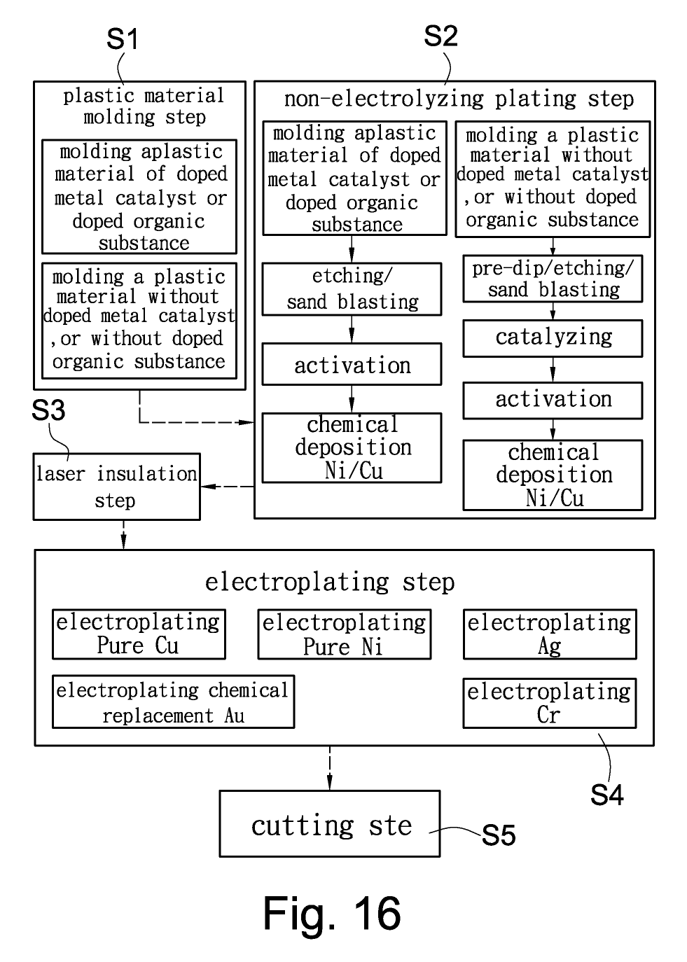

Two preferred embodiments about the fabrication method of the carrier structure are described in FIG. 15 and FIG. 16, the method includes five steps, namely, a plastic material molding step S1, an electroless plating step S2, a laser beam radiation step S3, an electroplating step S4 and a cutting step S5 to be carried out successively. Such a fabrication method is defined as Single-shot Plating and Laser (SPL) process in the present invention.

In the step S1, at least a carrier 1 extending at least one side arm 11 is formed of a plastic material or LED high molecular polymer by molding, wherein the plastic material is selected one from polyamide (PA), PBT, PET, LCP, PC, ABS and PC/ABS.

The carrier 1 is made of a doped metal catalyst containing plastic material, or a doped organic substance containing plastic material. The metal catalyst is selected one from Pd, Cu, Ag, and Fe. Alternatively, the carrier 1 may be made of a plastic material without any doped catalyst, or a plastic material without any doped organic substance.

In step S2, an interface layer 2 is formed on the carrier 1 prepared in the former step 1 to enclose the carrier 1 thereby making a fundamental material of the carrier 1 to load the electronic components. In case the carrier 1 is made of a doped metal catalyst containing plastic material, or a doped organic substance containing plastic material, the surface thereof passes through electroless plating treatment of chemical etching or sand blasting and activation, and the Ni or Cu is deposited on the surface of the carrier 1 so as to form the interface layer 2. In case the carrier is made of a plastic material without nay doped catalyst, or a plastic material without any doped organic substance, the surface thereof passes through electroless plating treatment of pre-dipping, chemical etching or sand blasting so as to texture its surface, after that the surface thereof is catalyzed and activated. Finally the surface thereof is plated a layer of Ni or Cu by chemical deposition. FIG. 15 shows the flow chart of surface texturization by chemical etching or sand blasting, while FIG. 16 shows the flow chart of surface texturization by pre-dipping, chemical etching or sand blasting.

In laser radiation step S3; the insulation path 3 is formed on the interface layer 2. In case the carrier 1 has no side arm 11, the laser beam is radiated so as to form the insulation path encircling the carrier 1 (see FIG. 3 and FIG. 4). In case the carrier 1 has at least one side arm 11 extending out of at least one side thereof, a front and a back insulation paths 31, 32 are formed on the interface layer 2 by ablating part of it and extended to pass across the fringe of the carrier 1 until the surface are of the side arm after completion forming of the interface layer 2 by deposition. In this laser beam insulation process, the fine insulation path, which is formed on the interface layer including the reflection cup 13, employs a simple but dexterous technique, and the pattern of the insulation path is open free to the designer's choice. In the laser beam radiation, laser is selected one from CO² laser, Nd:YAG laser, Nd:YVO4 crystal laser and excimer laser.

In step 4, a metal layer 4 is formed on the interface layer 2 by electroplating metal one selected from Cu, Ni, Ag, Au, Cr and chemical replacement Cu to complete fabrication of the carrier structure for the electronic components suitable for affixing light emission chips and wiring.

In the final step S5, the side arm or arms 11 if any, is separated from the carrier 1 by cutting or punching and shearing such that a bonding surface 16 between the carrier 1 and its side arm or arms 11, the front and the rear insulation paths 31, 32 split the carrier 1 into a positive pole 14 and a negative pole 15.

It emerges from the description of the above embodiments that the invention has several noteworthy advantages compared with the conventional techniques, in particular:

1. The difficulty arises from the formation of very fine insulation path or conductor wiring is solved by the technique of laser beam ablation.

2. The carrier fabricated according to the present invention is not only applicable to affix the LED chip and conductor wiring, but also serves for effective heat dissipation with its large heat conducting area formed of the reflection cup with the aid of the connected metal layer. The figure and the size of the carrier can be freely designed according to the actual needs with a low production cost.

Many changes and modifications in the above-described embodiments of the invention can, of course, be carried out without departing from the scope thereof. Accordingly, to promote the progress in science and the useful arts, the invention is disclosed and intended to be limited only by the scope of the appended claims.

What is claimed is:

1. A carrier structure for electronic components, comprising:
a carrier;
an interface layer formed on the surface of said carrier by electroless plating:
insulation paths formed on the surface of said carrier by ablating part of said interface layer by laser beam radiation; and
a metal layer formed on said interface layer by electroplating.

2. The carrier of claim 1, wherein said carrier, which is a plastic material with doped metal catalyst, or a plastic material with doped organic substance, passes through surface texturization by chemical etching or sand blasting, and then activated before electroless plating.

3. The carrier of claim 1, wherein said carrier, which is a plastic material without doped metal catalyst, or a plastic material without doped organic substance, passes through surface texturization by pre-dipping, chemical etching or sand blasting, and them modified by catalyzing and activated before electroless plating.

4. The carrier of claim 1, wherein said carrier has a slanted reflection surface with a reflection cup on top surface thereof, and the angle between said carrier surface and said reflection surface is from 15° to 85°.

5. The carrier of claim 1, wherein said insulation paths are formed on the upper, side, and lower surfaces of the carrier by ablating part of said interface layer such that said insulation paths part said carrier into a positive pole and a negative pole.

6. The carrier of claim 1, wherein at least one side is extended out of one side of said carrier, and depositing said interface layer on said carrier, afterwards forming a front and a back surface insulation paths on said carrier and said side arm by partly ablating said interface layer employing laser beam radiation.

7. The carrier of claim 6, wherein after said metal layer is deposited on said interface layer of said carrier and said side arm, said side arm is cut off from said carrier such that a bonding surface between said carrier and said side arm, and said front and said back surface insulation paths divide said carrier into a positive pole and a negative pole.

8. A fabrication method of a carrier structure for electronic components, comprising:
a plastic material molding step: providing at least a carrier;
an electroless plating step: forming an interface layer on said carrier;
a laser beam insulation step: ablating part of said interface layer to form insulation paths on the upper, side and lower surfaces of said carrier; and
an electroplating step: forming a metal layer on said interface layer.

9. A fabrication method of a carrier structure for electronic components, comprising:
a plastic material molding step: forming a carrier having at least a side arm extended from one side thereof,
an electroless plating step: forming an interface layer on said carrier and said side arm by chemical deposition;
a laser beam radiation step: forming a front and a back insulation paths on said interface layer of said carrier and said side arm by ablating part of said interface layer;
an electroplating step: forming a metal layer on said interface layer;
a cutting step: cutting said side arm from said carrier thereby completing the fabrication of the carrier structure for electronic components.

10. The method of claim 9, wherein said carrier is a plastic material doped with a metal catalyst, or a plastic material doped with an organic substance.

11. The method of claim 9, wherein said carrier is a plastic material without doped metal catalyst, or a plastic material without doped organic material.

12. The method of claim 9, wherein the surface of said carrier is textured by pre-dipping, chemical etching or sand blasting, then catalyzed and activated before electroless plating.

13. The method of claim 9, wherein said interface layer is formed on said carrier by chemically depositing Ni or Cu in electroless plating process after being activated.

14. The method of claim 9, wherein said front and rear insulation paths extended to the side arms of said carrier are formed on said interface layer by ablating part of said interface layer employing said laser beam radiation.

15. The method of claim 9, wherein in said cutting process, said side arm is cut to separate from said carrier such that a bonding surface between said side arm and said carrier, together with said front and said back surface insulation paths split said carrier into a positive pole and a negative pole.
